(19) United States
(12) Patent Application Publication
(10) Pub. No.: US 2013/0113493 A1
(43) Pub. Date: May 9, 2013

(54) PROTECTIVE SEMICONDUCTOR APPARATUS FOR AN ASSEMBLED BATTERY, A BATTERY PACK INCLUDING THE PROTECTIVE SEMICONDUCTOR APPARATUS, AND AN ELECTRONIC DEVICE

(71) Applicant: Junichi Kanno, Kanagawa (JP)

(72) Inventor: Junichi Kanno, Kanagawa (JP)

(21) Appl. No.: 13/808,961

(22) PCT Filed: Jul. 7, 2011
(86) PCT No.: PCT/JP2011/066027

§ 371 Date: Jan. 8, 2013

(30) Foreign Application Priority Data
Jul. 14, 2010 (JP) 2010 159379

(51) Int. Cl. G01R 31/36

(52) U.S. Cl. 324/426

(57) ABSTRACT

A protective semiconductor apparatus for protecting an assembled battery including N secondary cells connected in series includes a disconnection detecting circuit including, for each of the N secondary cells, a voltage-sensing resistor dividing a voltage of a corresponding one of the secondary cells, a reference voltage, and a first comparator comparing a voltage obtained by the voltage-sensing resistor with the reference voltage. The protection semiconductor apparatus also includes a circuit connecting an internal resistor having a resistance value smaller than a resistance value of a corresponding one of the voltage-sensing resistors in parallel to the corresponding voltage-sensing resistors successively and selectively at predetermined time intervals. The disconnection detecting circuit detects disconnection between the N secondary cells and the protective semiconductor apparatus based on an output from the first comparator when the internal resistor is connected in parallel to the corresponding voltage-sensing resistor.

### TECHNICAL FIELD

The present invention relates to a technology for protecting an assembled battery including a series connection of plural secondary cells.

### BACKGROUND ART

In various portable electronic devices, such as portable personal computers, audio devices, cameras, and video devices, battery packs are widely used due to their ease of handling. A battery pack consists of one or more secondary cells housed within a package. The secondary cells may include lithium ion cells, lithium polymer cells, and nickel metal hydride cells, which all have high capacity. A high-capacity cell can store a very large amount of energy, so that the cell may heat up or even cause fire and pose danger to the human body if over-charged, over-discharged, or an over-current flows in it.

Thus, a protective semiconductor apparatus for protecting the secondary cells from over-charging, over-discharging, an over-charge current, an over-discharge current, a short-circuit current, or abnormal over-heating may be provided within the battery pack. In the event that protection from any of the above abnormalities is required, the protection semiconductor apparatus terminates the connection between the secondary cells and a charging unit or a load device in order to prevent over-heating or fire and also to prevent degradation of the secondary cells.

There have also been proposed protective semiconductor apparatuses for protecting plural secondary cells connected in series in an assembled battery. For example, Japanese Laid-open Patent Publication No. 2008-027658 (Patent Document 1) proposes a protective semiconductor apparatus capable of detecting disconnection between the secondary cells and the protective semiconductor apparatus.

The technology according to Patent Document 1 is aimed at detecting disconnection between the secondary cells and the protecting unit. It is based on a method whereby a cell voltage in the presence of a charge or discharge current flow is compared with a cell voltage in the absence of any charge or discharge current flow. More specifically, the technology is directed to a method for detecting disconnection in a battery pack including one or more stages of series connections of cell blocks, each of the cell blocks including plural cells connected in parallel. The terminal voltage of a cell block is measured in a charge or discharge period and a period in which substantially no charge or discharge current is flowing. The method then obtains a terminal voltage difference between these periods, and determines an internal resistance value of the cells from the terminal voltage difference and a charge or discharge current value in the charge or discharge period. When the internal resistance value exceeds a predetermined value, the method determines that at least one of the parallel cells is disconnected (detached).

The above protective semiconductor apparatus for protecting plural secondary cells connected in series can detect disconnection between the secondary cells and the protecting unit. However, the detection of disconnection is performed in the charge or discharge period and the period when there is substantially no charge or discharge current. Thus, the method is not capable of detecting disconnection between the secondary cells and the protecting unit during the use of the secondary cells.

### DISCLOSURE OF INVENTION

In view of the above, it is an object of the present invention to provide a protective semiconductor apparatus capable of detecting disconnection between a secondary cell and a protective semiconductor apparatus even during the use of the secondary cell, a battery pack containing the protective semiconductor apparatus, and an electronic device containing the protective semiconductor apparatus or the battery pack.

In one aspect of the present invention, a protective semiconductor apparatus for protecting an assembled battery including N secondary cells connected in series includes a disconnection detecting circuit including, for each of the N secondary cells, a voltage-sensing resistor configured to divide a voltage of the secondary cell, a reference voltage, and a first comparator configured to compare a voltage obtained by the voltage-sensing resistor with the reference voltage; and a circuit configured to connect an internal resistor having a resistance value smaller than a resistance value of a corresponding one of the voltage-sensing resistors in parallel to the corresponding voltage-sensing resistors successively and selectively at predetermined time intervals. The disconnection detecting circuit is configured to detect disconnection between the N secondary cells and the protective semiconductor apparatus based on an output from the first comparator when the internal resistor is connected in parallel to the corresponding voltage-sensing resistor.

In another aspect, a battery pack includes the protective semiconductor apparatus.

In another aspect, an electronic device includes the protective semiconductor apparatus or the battery pack.

In accordance with the protective semiconductor apparatus according to an embodiment, connection between the secondary cells and the protective semiconductor apparatus is monitored at predetermined time intervals. Thus, disconnection between the secondary cells and the protective semiconductor apparatus can be detected even during the use of the secondary cells. Further, the size of the protective semiconductor apparatus can be reduced by sharing of circuit components.

A battery pack or an electronic device according to an embodiment includes the protective semiconductor apparatus. Thus, disconnection between the secondary cells and the protective semiconductor apparatus can be detected even during the use of the secondary cells. Further, the size of the battery pack or the electronic device can be reduced by sharing circuit components.

### BRIEF DESCRIPTION OF THE DRAWINGS

The foregoing and other objects, features and advantages of the invention will be apparent from the following more particular description of embodiments of the invention, as illustrated in the accompanying drawings in which:

FIG. 1 is a connecting diagram of a protective semiconductor apparatus according to a first embodiment;

FIG. 2 illustrates control signals from a control circuit of the protective semiconductor apparatus of FIG. 1;

FIG. 3 is a timing chart illustrating an operation of the protective semiconductor apparatus according to the first embodiment upon disconnection;

FIG. 4 is a circuit diagram for illustrating an operation of the protective semiconductor apparatus according to the first embodiment, particularly a VC1 disconnection detecting circuit and a VSS disconnection detecting circuit;

FIG. 5 is an operation time chart illustrating an operation of the protective semiconductor apparatus for high-voltage detection;

FIG. 6 is a connecting diagram of the protective semiconductor apparatus according to a second embodiment;

FIG. 7 is an operation timing chart illustrating an operation of the protective semiconductor apparatus according to the second embodiment for disconnection detection;

FIG. 8 is an operation time chart illustrating an operation of the protective semiconductor apparatus according to the second embodiment for low-voltage detection;

FIG. 9 is a connecting diagram of the protective semiconductor apparatus according to a third embodiment;

FIG. 10 is a connecting diagram of the protective semiconductor apparatus according to a fourth embodiment;

FIG. 11 is a connecting diagram of the protective semiconductor apparatus according to a fifth embodiment; and

FIG. 12 is a connecting diagram of the protective semiconductor apparatus according to a sixth embodiment.

### BEST MODE OF CARRYING OUT THE INVENTION

### (Features of the Invention)

The protective semiconductor apparatus for protecting plural secondary cells connected in series according to an embodiment of the present invention has the following features. The protective semiconductor apparatus includes voltage-sensing resistors for voltage division connected in parallel with the secondary cells for voltage monitoring. An internal resistor whose value is smaller than those of the voltage-sensing resistors is connected in parallel with at least one of the voltage-sensing resistors (such as the voltage-sensing resistors corresponding to every other secondary cells) at predetermined time intervals.

When there is no disconnection between the protective semiconductor apparatus and the secondary cells, no voltage variation due to the secondary cells is caused at a cell connecting terminal for connection with the secondary cells. However, when there is disconnection between the protective semiconductor apparatus and the secondary cells, the voltage at the cell connecting terminal disconnected from the secondary cells varies in accordance with a variation in resistance value. Thus, the voltage variation due to the change in resistance value is detected as having been caused by disconnection.

A power supply terminal (i.e., a cell-connecting terminal VC1 for the positive electrode of an upper-most secondary cell) of the protective semiconductor apparatus and a ground terminal (VSS) affect a stable operation of the protective semiconductor apparatus. Thus, the protective semiconductor apparatus may include a circuit for instantaneously detecting disconnection of the power supply terminal (VC1) or the ground terminal (VSS) from the secondary cells.

### (Outline of Various Embodiments)

In accordance with a basic embodiment of the present invention, connection between the secondary cells and the protective semiconductor apparatus is monitored at predetermined time intervals in order to detect disconnection even during the use of the secondary cells.

Some of the constituent elements or components of a disconnection detecting circuit may be shared with a high-voltage detecting circuit and/or a low-voltage detecting circuit. Thus, in the first and second embodiments described below, some of the constituent elements of the disconnection detecting circuit are shared with the high-voltage detecting circuit and/or the low-voltage detecting circuit in order to reduce circuit size.

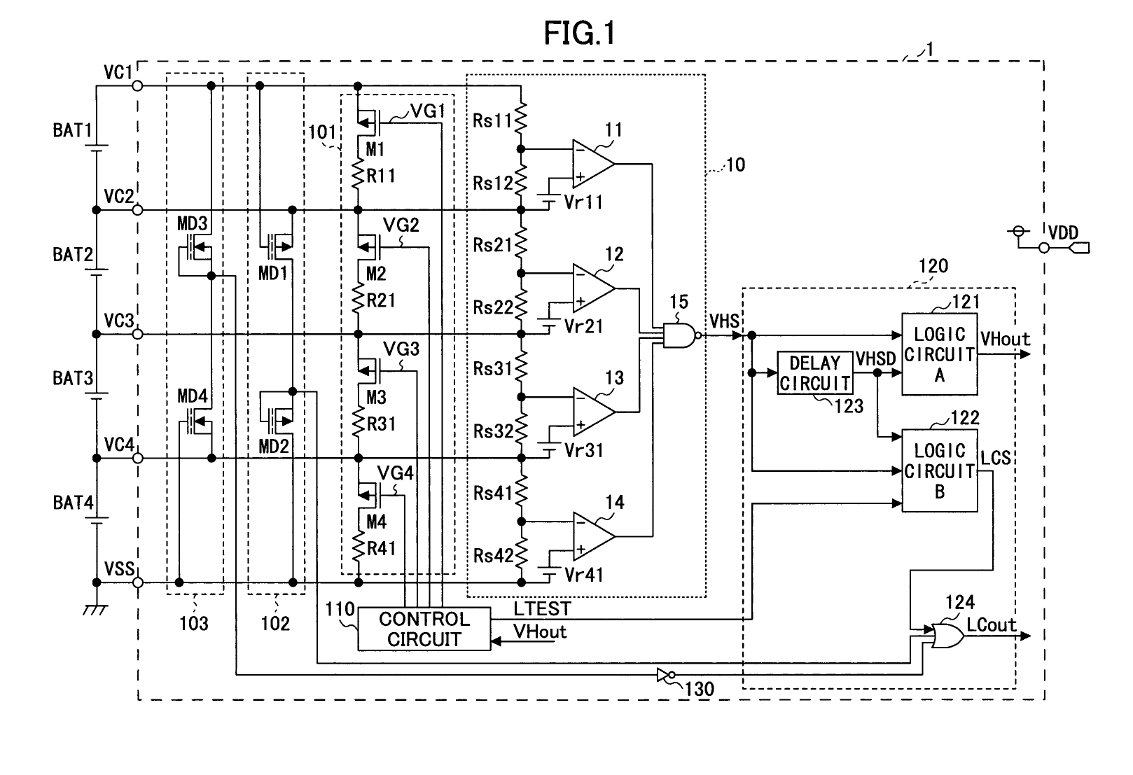

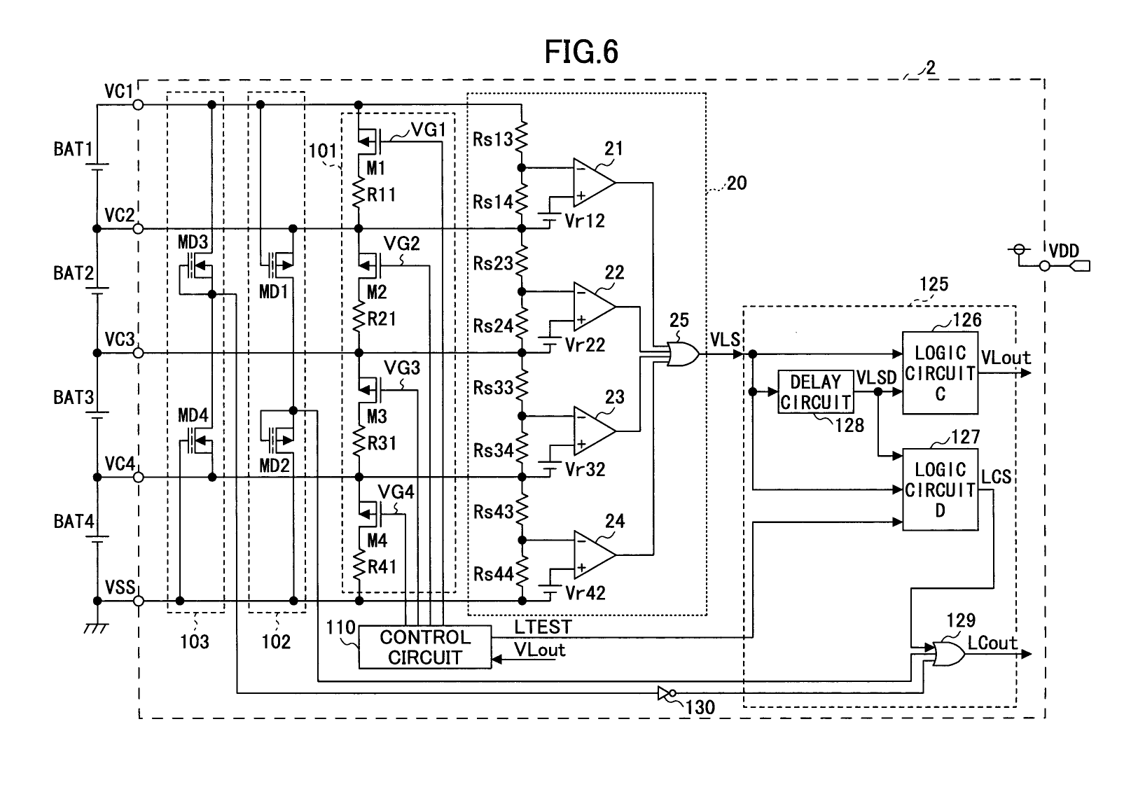

Specifically, in the first embodiment (see FIG. 1), voltage-sensing resistors Rs11 through Rs42, reference voltages Vr11 through Vr41, comparators 11 through 14, and a NAND circuit 15 in the disconnection detecting circuit are shared with a high-voltage detecting circuit (for this reason, the disconnection detecting circuit may be referred to as a “disconnection/high-voltage detecting circuit”). In the second embodiment (see FIG. 6), voltage-sensing resistors Rs13 through Rs44, reference voltages Vr12 through Vr42, comparators 21 through 24, and an OR circuit 25 in the disconnection detecting circuit are shared with a low-voltage detecting circuit (for this reason, the disconnection detecting circuit may be referred to as a “disconnection/low-voltage detecting circuit”).

The characteristics of the voltage-sensing resistors Rs11 through Rs42 and the reference voltages Vr11 through Vr41 of the first embodiment need not be particularly limited when only used as a disconnection detecting circuit. However, when also used as a high-voltage detecting circuit, the characteristics need to be such that the comparators 11 through 14 are inverted upon detection of a value considered to be a high voltage.

Similarly, the characteristics of the voltage-sensing resistors Rs13 through Rs44 and the reference voltages Vr12 through Vr42 of the second embodiment need not be particularly limited when used only as a disconnection detecting circuit. However, when also used as a low-voltage detecting circuit, the characteristics need to be such that the comparators 21 through 24 are inverted upon detection of a value considered to be a low-voltage.

A third embodiment is directed to a protective semiconductor apparatus including a disconnection/high-voltage detecting circuit similar to the one of the first embodiment and a disconnection/low-voltage detecting circuit similar to the one of the second embodiment. In the third embodiment, detection of disconnection may be made by using the voltage-sensing resistors, the reference voltages, and the comparators of one of the disconnection/high-voltage detecting circuit and the disconnection/low-voltage detecting circuit. Alternatively, both the disconnection/high-voltage detecting circuit and the disconnection/low-voltage detecting circuit may be used and disconnection may be detected upon detection of disconnection by at least one of them.

In a fourth embodiment, it is made possible to determine which connection is disconnected in the first embodiment. In a fifth embodiment, it is made possible to determine which connection is disconnected in the third embodiment. In a sixth embodiment, a VC1 disconnection detecting circuit and a VSS disconnection detecting circuit are realized by using comparators instead of inverters used in the first through fifth embodiments.

### EMBODIMENTS

The first through sixth embodiments of the present invention are described with reference to the drawings.

### First Embodiment

FIG. 1 is a connecting diagram of the protective semiconductor apparatus 1 according to the first embodiment, illustrating the connection between the protective semiconductor apparatus 1 and secondary cells. As illustrated in FIG. 1, the protective semiconductor apparatus 1 includes a disconnection/high-voltage detecting circuit 10, an internal resistor changing circuit 101, a VC1 disconnection detecting circuit 102, a VSS disconnection detecting circuit 103, a control circuit 110, and a determination circuit 120.

While not illustrated in FIG. 1, the protective semiconductor apparatus 1 may also include a disconnection/low-voltage detecting circuit and an over-current detecting circuit. While FIG. 1 illustrates the case where there are four secondary cells, the number of the secondary cells is not particularly limited.

The protective semiconductor apparatus 1 has cell connecting terminals VC1 through VC4 for connecting the four secondary cells, a ground terminal VSS, and a power supply terminal VDD. To the cell connecting terminal VC1, the positive electrode of the upper-most (first) cell BAT1 is connected. To the cell connecting terminal VC2, the negative electrode of the first cell BAT1 and the positive electrode of the second cell BAT2 are connected. To the cell connecting terminal VC3, the negative electrode of the second cell BAT2 and the positive electrode of the third cell BAT3 are connected. To the cell connecting terminal VC4, the negative electrode of the third cell BAT3 and the positive electrode of the fourth cell BAT4 are connected. To the ground terminal VSS (ground voltage), the negative electrode of the lower-most (fourth) cell BAT4 is connected. The power supply terminal VDD is connected to a power supply of a circuit (not illustrated) and the cell connecting terminal VC1, for example.

The disconnection/high-voltage detecting circuit 10 enclosed by a broken line includes comparators 11 through 14, reference voltages Vr11 through Vr41, voltage-sensing resistors Rs11 through Rs42, and a NAND circuit 15. The comparator 11, the voltage-sensing resistors Rs11 and Rs12, and the reference voltage Vr11 constitute a circuit for detecting a high voltage of the first cell BAT1. The voltage-sensing resistors Rs11 and Rs12 are connected in series between the cell connecting terminals VC1 and VC2. A connecting node of the voltage-sensing resistors Rs11 and Rs12 is connected to an inverting input of the comparator 11. The reference voltage Vr11 is connected between a non-inverting input of the comparator 11 and the cell connecting terminal VC2. Thus, the voltage-sensing resistors Rs11 and Rs12 are associated with the first cell BAT1.

The configuration of the disconnection/high-voltage detecting circuit 10 for the second cell BAT2 through the fourth cell BAT4 may be the same as for the above-described configuration for the first cell BAT1.

Outputs from the comparators 11 through 14 are input to the NAND circuit 15. The NAND circuit 15 outputs a detection signal VHS to the determination circuit 120.

The internal resistor changing circuit 101 enclosed by another broken line includes PMOS transistors M1 through M4, and internal resistors R11 through R41. The PMOS transistor M1 and the internal resistor R11 constitute an internal resistor changing circuit for the first cell BAT1. The MOS transistor M1 and the resistor R11 are connected in series between the cell connecting terminals VC1 and VC2. The gate of the PMOS transistor M1 receives a MOS control signal VG1 from the control circuit 110. Description of the internal resistor changing circuits for the second cell BAT2 through the fourth cell BAT4 are omitted as they are identical to the internal resistor changing circuit for the first cell BAT1.

The internal resistors R11 through R41 have identical resistance values smaller than the resistance values of the voltage-sensing resistors Rs11 through Rs42 of the disconnection/high-voltage detecting circuit 10.

While the illustrated example of FIG. 1 employs PMOS transistors, NMOS transistors may be used (in which case the MOS control signals VG1 through VG4 from the control circuit 110 would be changed as a matter of course).

The VC1 disconnection detecting circuit 102 includes PMOS depletion-type transistors MD1 and MD2. The PMOS depletion-type transistors MD1 and MD2 are connected in series between the cell connecting terminal VC2 and the ground terminal VSS. The gate of the PMOS depletion-type transistor MD1 is connected to the cell connecting terminal VC1. The gate of the PMOS depletion-type transistor MD2 is connected to a connecting node of the PMOS depletion-type transistors MD1 and MD2. The connecting node of the PMOS depletion-type transistors MD1 and MD2 is connected to an OR circuit 124 in the determination circuit 120.

By connecting the gate of the PMOS depletion-type transistor MD1 to the power supply terminal VDD, detection of disconnection between the protective semiconductor apparatus 1 and the secondary cells is enabled.

The VSS disconnection detecting circuit 103 includes NMOS depletion transistors MD3 and MD4. The NMOS depletion transistors MD3 and MD4 are connected in series between the cell connecting terminal VC1 and the cell connecting terminal VC4. The gate of the PMOS depletion-type transistor MD3 is connected to a connecting node of the PMOS depletion-type transistors MD3 and MD4. The gate of the PMOS depletion-type transistor MD4 is connected to the ground terminal VSS. The connecting node of the PMOS depletion-type transistors MD3 and MD4 is connected to the OR circuit 124 in the determination circuit 120 via the inverter circuit 130.

The control circuit 110 receives a high voltage detection signal VHout as an input and outputs control signals VG1 through VG4 to the gates of the PMOS transistors M1 through M4 of the internal resistor changing circuit 101. The control circuit 110 also outputs a disconnection confirmation signal LTEST to the logic circuit B 122.

While not illustrated, in order to generate the control signals VG1 through VG4 and the disconnection confirmation signal LTEST, a clock signal from an oscillating circuit or an external trigger signal may be input to the control circuit 110, or an external capacitor may be connected to the control circuit 110.

The determination circuit 120 enclosed by a broken line is a circuit for determining whether high voltage detection or disconnection detection should be made. The determination circuit 120 includes a logic circuit A 121, a logic circuit B 122, a delay circuit 123, and the OR circuit 124.

The logic circuit A 121 receives the detection signal VHS from the disconnection/high-voltage detecting circuit 10 and a detection delay output VHSD from the delay circuit 123. The logic circuit A 121 outputs a high voltage detection signal VHout to an internal circuit (not illustrated).

The logic circuit B 122 receives the detection signal VHS from the disconnection/high-voltage detecting circuit 10, the disconnection confirmation signal LTEST from the control circuit 110, and the output VHSD from the delay circuit 123. The logic circuit B 122 outputs a disconnection determination signal LCS as one of the inputs to the OR circuit 124.

The delay circuit 123 receives the output VHS from the disconnection/high-voltage detecting circuit 10. The delay circuit 123 outputs the detection delay output VHSD to the logic circuit A and the logic circuit B.

The OR circuit 124 receives the disconnection detection signal LCS from the logic circuit B 122, an output from the VC1 disconnection detecting circuit 102, and an output from the VSS disconnection detecting circuit 103 via the inverter circuit 130. The OR circuit 124 outputs a disconnection detection signal LCout to the internal circuit (not illustrated).

The configuration of the determination circuit 120 is not particularly limited as long as it can determine whether high voltage detection or disconnection detection should be made.

The delay circuit 123 is a circuit for setting a detection/recovery delay time for preventing erroneous detection due to noise and the like. Operation of the delay circuit 123 may be started when the output VHS from the NAND circuit 15 is changed from “L” to “H” upon detection of a high voltage. The delay circuit 123 may output an H pulse in the output VHSD when the output VHS from the NAND circuit 15 is “H” until a set time elapses.

Operation of the delay circuit 123 may also be started when the output VHS from the NAND circuit 15 is changed from “H” to “L” upon recovery from the high voltage detection status. The delay circuit 123 may output an H pulse when the output VHS from the NAND circuit 15 is “L” until a set time elapses.

While not illustrated, the delay circuit 123 receives the output VHout from the logic circuit A 121 so that the delay circuit 123 can determine detection or recovery depending on the status of VHout. The set time for high voltage detection may differ from the set time for high voltage recovery. The configuration of the delay circuit 123 is not particularly limited as long as it can operate as described above. For example, the delay circuit 123 may include a counter, or it may be based on a system in which a capacitor is charged by a constant current.

The logic circuits A 121 and B 122 may include latch circuits. While not illustrated, the logic circuits A 121 and B 122 may exchange various signals with each other. The logic circuit A 121 latches the output VHS from the NAND circuit 15 upon rising of the H pulse in the output VHSD from the delay circuit 123. The logic circuit B 122 latches the output VHS from the NAND circuit 15 upon falling of the output LTEST from the control circuit 110.

Thus, in the absence of output of the H pulse in the output VHSD from the delay circuit 123 when the output VHS from the NAND circuit 15 is “H”, the logic circuit A 121 does not latch the signal of the output VHS from the NAND circuit 15, so that the output VHout from the logic circuit A 121 does not become “H”.

### (Operation of the Control Circuit)

For facilitating the description of the operation of the protective semiconductor apparatus 1, an operation of the control circuit 110 is described. In order to control the process of confirming the connection of the secondary cells and the protective semiconductor apparatus at regular intervals twait, the control circuit 110 may generate the control signals VG1 through VG4 and the disconnection confirmation signal LTEST based on a clock input to the control circuit 110.

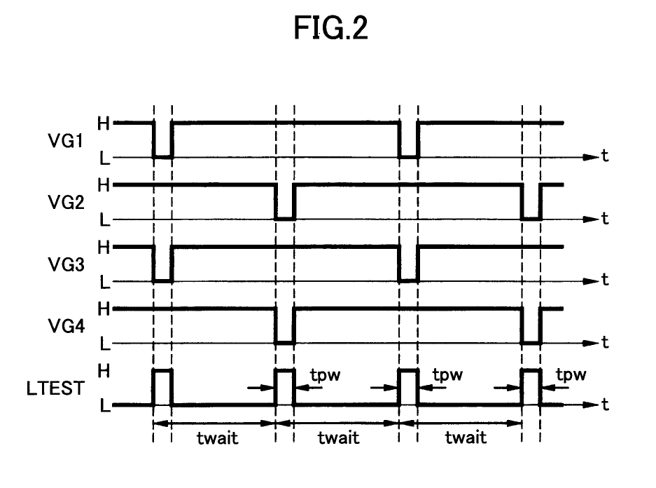

FIG. 2 illustrates an example of the control signals from the control circuit 110 in the protective semiconductor apparatus 1 of FIG. 1. The control circuit 110 places the disconnection confirmation signal LTEST, via which the determination circuit 120 may be notified that disconnection confirmation is being made, in an “H” status for a time width tpw at regular time intervals twait.

In synchronism with the disconnection confirmation signal LTEST, at least one of the control signals VG1 through VG4 is placed in an “L” status, so that the PMOS transistors M1 through M4 connected to the corresponding control signals are turned on. Depending on the PMOS transistors that are turned on, the internal resistors R11, R21, R31, and R41 are connected in parallel to the voltage-sensing resistors Rs11 and Rs12, Rs21 and Rs22, Rs31 and Rs32, and Rs41 and Rs42, respectively.

The time intervals twait for confirmation of disconnection detection and the time tpw in which the disconnection confirmation signal LTEST is in the “H” status are not particularly limited. In the illustrated example, the disconnection confirmation time tpw is shorter than the delay time for high voltage detection set by the delay circuit 123.

The method of setting the time intervals twait for disconnection detection confirmation and the time tpw in which the disconnection confirmation signal LTEST is in the H status is not particularly limited. For example, they may be set by adjusting the intervals of trigger input from outside the protective semiconductor apparatus; by using an oscillating circuit provided inside the protective semiconductor apparatus 1; or by using a capacitor provided externally to the protective semiconductor apparatus.

### (Operation of the Protective Semiconductor Apparatus)

For ease of description, it is assumed that voltages VBAT1 through VBAT4 of the secondary cells BAT1 through BAT4, respectively, and the resistance values of the voltage-sensing resistors Rs11 through Rs42 in the example of FIG. 1 have the following relationships:

VBAT1=VBAT2=VBAT3=VBAT4 (1.1)

Rs11+Rs12=Rs21+Rs22=Rs31+Rs32=Rs41+Rs42 (1.2)

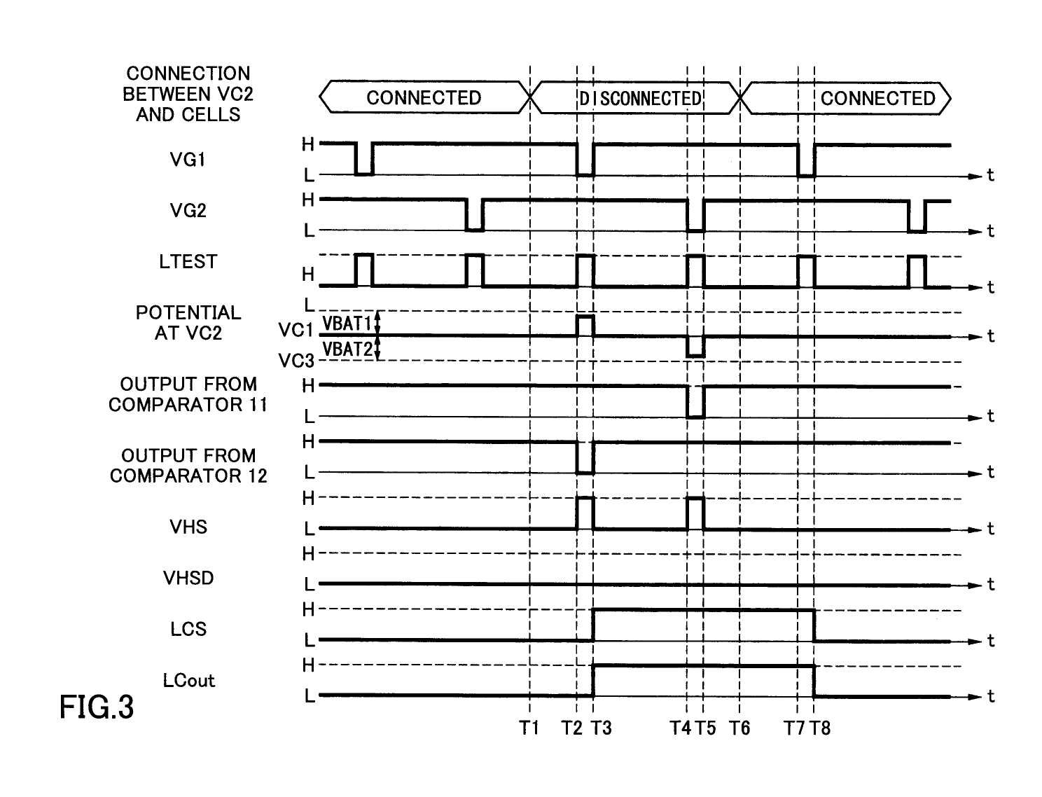

FIG. 3 is a timing chart of an operation of the protective semiconductor apparatus 1 according to the first embodiment in the event of disconnection. The time chart illustrates only those signals necessary for the description of the operation. In the following, the time chart is described along the time axis.

### <Time T1>

At time T1, disconnection occurs between the secondary cells and the cell connecting terminal VC2. In this case, a voltage V2A between the cell connecting terminals VC2 and VC3 is given by the division of voltage by the voltage-sensing resistors Rs11 through Rs22 according to the following expression:

$$V 2 A = \frac{Rs 21 + Rs 22}{Rs 11 + Rs 12 + Rs 21 + Rs 22} \times ( VBAT 1 + VBAT 2 ) \qquad ( 1.3 )$$

According to expressions (1.1), (1.2), and (1.3), the voltage V2A between the cell connecting terminals VC2 and VC3 is not changed from the voltage VBAT2 before disconnection. Thus, none of the outputs from the comparators 11 through 14 is changed.

### <Time T2>

At time T2, the disconnection confirmation signal LTEST from the control circuit 110 is switched from “L” to “H”, thus notifying the logic circuit B 122 that disconnection detection confirmation is being made, while the control signal VG1 is switched from “H” to “L” to turn on the PMOS transistor M1. As a result, the internal resistor R11 is connected in parallel to the series circuit of the voltage-sensing resistors Rs11 and Rs12. Thus, a voltage V2B between the cell connecting terminals VC2 and VC3 is calculated according to the following expression:

$$V 2 B = \frac{Rs 21 + Rs 22}{\frac{R 11 \times ( Rs 11 + Rs 12 )}{R 11 + Rs 11 + Rs 12} + Rs 21 + Rs 22} \times ( VBAT 1 + VBAT 2 ) \qquad ( 1.4 )$$

When the internal resistor R11 is sufficiently small compared to the sum of the voltage-sensing resistors Rs11 and Rs12 (which is the case in the present embodiment), the voltage between the cell connecting terminals VC2 and VC3 becomes substantially equal to a voltage V2C calculated according to the following expression.

$$V 2 C = \frac{Rs 21 + Rs 22}{R 11 + Rs 21 + Rs 22} \times ( VBAT 1 + VBAT 2 ) \qquad ( 1.5 )$$

According to expression (1.4) or (1.5), the potential at the cell connecting terminal VC2 is increased to approach the potential at the cell connecting terminal VC1, which is the connecting terminal for the positive electrode of the secondary cell BAT1. As a result, the voltage between the cell connecting terminals VC2 and VC3 is increased. Thus, the comparator 12 detects a high voltage, and the output from the comparator 12 is inverted to “L”, indicating a high voltage detection status (while the outputs from the other comparators 11, 13, and 14 remain at H). Thus, the output from the NAND circuit 15, i.e., the detection signal VHS from the disconnection/high-voltage detecting circuit 10, is inverted from L to H.

### <Time T3>

At time T3, the disconnection confirmation signal LTEST from the control circuit 110 is switched from H to L, thus notifying the logic circuit B 122 of the end of disconnection detection confirmation, while the control signal VG1 is switched from L to H in order to turn off the PMOS transistor M1. As a result, the parallel connection of the internal resistor R11 and the voltage-sensing resistors Rs11 and Rs12 is eliminated, so that the voltage between the cell connecting terminals VC2 and VC3 is returned back to the voltage V2A calculated according to the expression (1.3). Thus, the output from the comparator 12 is again inverted to “H” indicating a non-detection status. Then, the output from the NAND circuit 15, i.e., the detection signal VHS from the disconnection/high-voltage detecting circuit 10, is inverted from H to L.

Because the output VHSD from the delay circuit 123 did not become H in the period in which the detection signal VHS from the disconnection/high-voltage detecting circuit 10 is at H in accordance with the disconnection confirmation signal LTEST, the logic circuit B 122 determines that there is disconnection, and inverts the disconnection determination signal LCS to H indicating a disconnection detection status. Upon reception of the disconnection determination signal LCS (H) from the logic circuit B 122, the OR circuit 124 inverts its output, i.e., the disconnection detection signal LCout, to H indicating the disconnection detection status.

### <Time T4>

At time T4, the disconnection confirmation signal LTEST from the control circuit 110 is switched from L to H, thus notifying the logic circuit B 122 that disconnection detection confirmation is being made, while the control signal VG2 is switched from H to L in order to turn on the PMOS transistor M2. As a result, the internal resistor R21 is connected in parallel to the series circuit of the voltage-sensing resistors Rs21 and Rs22. Thus, a voltage V2D between the cell connecting terminals VC2 and VC3 is calculated according to the following expression.

$$V 2 D = \frac{\frac{R 21 \times ( Rs 21 + Rs 22 )}{R 21 + Rs 21 + Rs 22}}{Rs 11 + Rs 12 + \frac{R 21 \times ( Rs 21 + Rs 22 )}{R 21 + Rs 21 + Rs 22}} \times ( VBAT 1 + VBAT 2 ) \qquad ( 1.6 )$$

When the internal resistor R21 is sufficiently small compared to the sum of the voltage-sensing resistors Rs21 and Rs22 (which is the case in the present embodiment), the voltage between the cell connecting terminals VC2 and VC3 is substantially equal to a voltage V2E calculated according to the following expression.

$$V 2 E = \frac{Rs 21}{Rs 11 + Rs 12 + R 21} \times ( VBAT 1 + VBAT 2 ) \qquad ( 1.7 )$$

According to the expression (1.6) or (1.7), the potential at the cell connecting terminal VC2 is decreased to approach the potential at the cell connecting terminal VC3, which is the connecting terminal for the negative electrode of the secondary cell BAT2. As a result, the voltage between the cell connecting terminals VC2 and VC3 decreases. Conversely, the voltage VIA between the cell connecting terminals VC1 and VC2 increases according to an expression (1.8) indicated below. Thus, the comparator 11 detects a high voltage and inverts its output to L indicating the detection status. As a result, the output from the NAND circuit 15, i.e., the detection signal VHS from the disconnection/high-voltage detecting circuit 10, is inverted from L to H.

V1A=VBAT+VBAT2−V2E (1.8)

### <Time T5>

At time T5, the disconnection confirmation signal LTEST from the control circuit 110 is switched from H to L, thus notifying the logic circuit B 122 of the end of disconnection detection confirmation, while the control signal VG2 is switched from L to H in order to turn off the PMOS transistor M2. Thus, the parallel connection of the internal resistor R21 and the series circuit of the voltage-sensing resistors Rs21 and Rs22 is eliminated, so that the voltage between the cell connecting terminals VC2 and VC3 is returned to the voltage V2A calculated according to the expression (1.3). As a result, the output from the comparator 11 is again inverted to the non-detection status H, so that the output from the disconnection/high-voltage detecting circuit 10, i.e., the detection signal VHS, is inverted from H to L.

Because the output VHSD from the delay circuit did not become H in the period in which the output VHS from the disconnection/high-voltage detecting circuit 10 was H in accordance with the disconnection confirmation signal LTEST, the logic circuit B 122 determines that there is disconnection, and maintains the disconnection determination signal LCS at H indicating the disconnection detection status. In response to the disconnection determination signal LCS, the OR circuit 124 maintains its output, i.e., the disconnection detection signal LCout, at H indicating the disconnection detection status.

### <Time T6>

The disconnected portion is corrected at time T6 in response to the disconnection detection.

### <Time T7>

At time T7, the disconnection confirmation signal LTEST from the control circuit 110 is switched from L to H, thus notifying the logic circuit B 122 that disconnection detection confirmation is being made, while the control signal VG1 is switched from H to L in order to turn on the PMOS transistor M1. As a result, the internal resistor R11 is connected in parallel to the series circuit of the voltage-sensing resistors Rs11 and Rs12. However, as opposed to the case of the time between T2 and T3 or the time between T4 and T5, the power supply connecting terminal VC2 is connected to the secondary cells. Thus, the voltage between the cell connecting terminals VC2 and VC3 is not changed from the VBAT2, so that the output VHS from the disconnection/high-voltage detecting circuit is not changed.

### <Time T8>

At time T8, the disconnection confirmation signal LTEST from the control circuit 110 is switched from H to L, thus notifying the logic circuit B 122 of the end of disconnection detection confirmation, while the control signal VG2 is switched from L to H in order to turn off the PMOS transistor M2. As at time T7, the power supply connecting terminal VC3 is connected to the secondary cells, so that the voltage between the cell connecting terminals VC2 and VC3 is not changed.

Because the output VHS from the disconnection/high-voltage detecting circuit 10 was not changed in accordance with the disconnection confirmation signal LTEST, the logic circuit B 122 determines that recovery from disconnection has been achieved, and inverts the disconnection determination signal LCS to the recovered status L. In response to the disconnection determination signal LCS, the OR circuit 124 inverts the disconnection detection signal LCout from the disconnection detection status to the recovered status L.

The operation is similar in cases of disconnection of the cell connecting terminal VC3 or the cell connecting terminal VC4; thus, description of the operation for these cases is omitted.

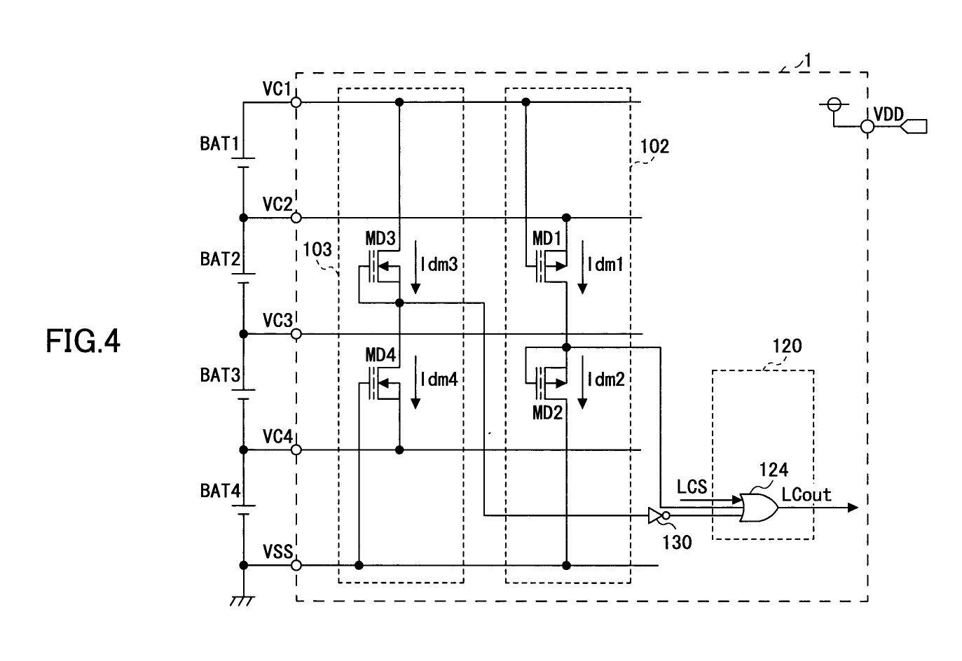

FIG. 4 is a circuit diagram of a portion of the protective semiconductor apparatus 1 according to the first embodiment that is related to the VC1 disconnection detecting circuit and the VSS disconnection detecting circuit. With reference to FIG. 4, an operation of the VC1 disconnection detecting circuit 102 and the VSS disconnection detecting circuit 103 is described.

The VC1 disconnection detecting circuit 102 includes a constant current inverter formed by a PMOS depletion-type transistor MD1 as a switch and a PMOS depletion-type transistor MD2 as a constant current load. When the cell connecting terminal VC1 is connected to the secondary cell BAT1, the gate voltage of the PMOS depletion-type transistor MD1 is higher than the source voltage by the voltage of the secondary cell BAT1, so that the PMOS depletion-type transistor MD1 is turned off. Thus, the potential at the connecting point of the PMOS depletion-type transistors MD1 and MD2 becomes equal to the ground terminal VSS (L).

However, when the cell connecting terminal VC1 is disconnected from the positive electrode of the secondary cell BAT1, the voltage applied to the cell connecting terminal VC1 becomes approximately equal to the cell connecting terminal VC2 due to the influence of an internal circuit. As a result, the gate voltage of the PMOS depletion-type transistor MD1 is lowered, thus turning on the PMOS depletion-type transistor MD1, so that the potential at the connecting point of the PMOS depletion-type transistors MD1 and MD2 becomes equal to the cell connecting terminal VC2 (H). Thus, the disconnection detection signal LCout from the OR circuit 124 is inverted from L to H.

The VSS disconnection detecting circuit 103 includes a constant current inverter formed by a NMOS depletion transistor MD4 as a switch and a NMOS depletion transistor MD3 as a constant current load. When the ground terminal VSS is connected to the secondary cell BAT1, the gate voltage of the NMOS depletion transistor MD4 becomes lower than the source voltage by the voltage of the secondary cell BAT4, so that the NMOS depletion transistor MD4 is turned off. Thus, the potential at the connecting point of the NMOS depletion transistors MD3 and MD4 becomes equal to the potential at the cell connecting terminal VC1(H).

However, when there is disconnection between the ground terminal VSS and the negative electrode of the secondary cell BAT4, the voltage applied to the ground terminal VSS becomes approximately equal to the voltage at the cell connecting terminal VC4 due to the influence of an internal circuit. As a result, the gate voltage of the NMOS depletion transistor MD4 is increased and the NMOS depletion transistor MD4 is turned on, so that the voltage at the connecting point of the NMOS depletion transistors MD3 and MD4 becomes equal to the cell connecting terminal VC4(L). As a result, the output from the inverter circuit 130 is inverted from L to H, so that the output from the OR circuit 124, i.e., the disconnection detection signal LCout, is inverted from L to H.

While in the illustrated example the VC1 disconnection detecting circuit 102 employs the PMOS depletion-type transistor MD2 as a constant current source and the VSS disconnection detecting circuit 103 employs the NMOS depletion transistor MD3 as a constant current source, the configuration of the VC1 disconnection detecting circuit 102 and the VSS disconnection detecting circuit 103 is not particularly limited as long as they include a circuit for producing a constant current.

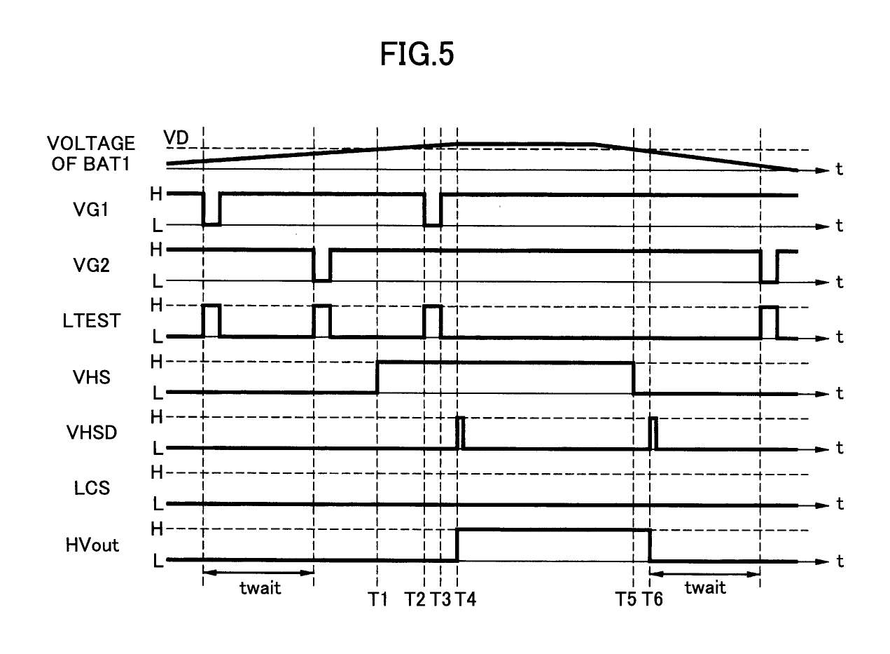

FIG. 5 is an operation time chart illustrating an operation of the protective semiconductor apparatus 1 according to the first embodiment upon detection of a high voltage. The time chart illustrates only those signals necessary for describing the operation. The timing chart is described along the time axis.

### <Time T1>

After charging of the secondary cells is started from a time, the voltage VBAT1 of the secondary cell BAT1 exceeds a high voltage detection voltage VD at time T1. Because the voltage VBAT1 of the secondary cell BAT1 has exceeded the high voltage detection voltage VD, the output from the comparator 11 is inverted to L, and the detection signal VHS from the disconnection/high-voltage detecting circuit 10 is inverted to H.

### <Time T2>

At time T2, the disconnection confirmation signal LTEST from the control circuit 110 is switched from L to H, thus notifying the logic circuit B 122 that disconnection detection confirmation is being made, while the control signal VG1 is switched from H to L in order to turn on the PMOS transistor M1. As a result, the internal resistor R11 is connected in parallel to the voltage-sensing resistors Rs11 and Rs12. However, because there is no disconnection, the cell connecting terminals VC1 through VC4 and the ground terminal VSS are not affected by the connection of the internal resistor R11. Because the voltage VBAT1 of the secondary cell BAT1 is higher than the high voltage detection voltage VD, the output from the disconnection/high-voltage detecting circuit 10, i.e., the detection signal VHS, remains at H.

### <Time T3>

At time T3, the disconnection confirmation signal LTEST from the control circuit 110 is switched from H to L, thus notifying the logic circuit B 122 of the end of disconnection detection confirmation, while the control signal VG1 is switched from L to H in order to turn off the PMOS transistor M2. However, because the voltage VBAT1 of the secondary cell BAT1 is higher than the high voltage detection voltage VD, the detection signal VHS from the disconnection/high-voltage detecting circuit 10 remains at H, as at time T2. As a result, the logic circuit B 122 determines that there is no disconnection and maintains the disconnection determination signal LCS at L.

### <Time T4>

At time T4, the delay time for high voltage detection elapses. Thus, the delay circuit 123 outputs a H pulse in the output VHSD, and the logic circuit A 121 inverts the high voltage detection signal VHout from L to H. As a result, the protective semiconductor apparatus 1 is placed in a high voltage detection status. Thus, the operation of the control circuit 110 is terminated by the high voltage detection signal VHout.

### <Time T5>

The voltage VBAT1 of the secondary cell BAT1 decreases due to the connection of a load, for example, and drops below the high voltage detection voltage VD at time T5. Then, the output from the comparator 11 is inverted to H. As a result, the detection signal VHS from the disconnection/high-voltage detecting circuit 10 is inverted to L.

### <Time T6>

At time T6, the delay time for recovery from high voltage detection elapses. Thus, the delay circuit 123 outputs an H pulse in the output VHSD, so that the logic circuit A 121 inverts the high voltage detection signal VHout from H to L. As a result, the protective semiconductor apparatus 1 is placed out of the high voltage detection status, and therefore the operation of the control circuit 110 is resumed.

### Second Embodiment

FIG. 6 is a connecting diagram of a protective semiconductor apparatus 2 according to the second embodiment. As illustrated, the protective semiconductor apparatus 2 includes a disconnection/low-voltage detecting circuit 20, the internal resistor changing circuit 101, the VC1 disconnection detecting circuit 102, the VSS disconnection detecting circuit 103, the control circuit 110, and a determination circuit 125.

While not illustrated, the protective semiconductor apparatus 2 may include the disconnection/high-voltage detecting circuit 10 illustrated in FIG. 1 or an over-current detecting circuit. While the illustrated example of FIG. 6 includes four secondary cells, the number of the secondary cells is not limited to four.

The disconnection/low-voltage detecting circuit 20 enclosed by a broken line includes comparators 21 through 24, reference voltages Vr12 through Vr42, voltage-sensing resistors Rs13 through Rs44, and an OR circuit 25. The comparator 21, the voltage-sensing resistors Rs13 and Rs14, and the reference voltage Vr12 constitute a circuit for detecting a low-voltage of the first cell BAT1.

The voltage-sensing resistors Rs13 and Rs14 are connected in series between the cell connecting terminals VC1 and VC2. A connecting node of the voltage-sensing resistors Rs13 and Rs14 is connected to an inverting input of the comparator 11. Between the non-inverting input of the comparator 21 and the cell connecting terminal VC2, a reference voltage Vr12 is connected. Thus, the voltage-sensing resistors Rs13 and Rs14 are associated with the first cell BAT1.

The configuration of the disconnection/low-voltage detecting circuit 20 for the second cell BAT2 through the fourth cell BAT4 may be the same as for the first cell BAT1. However, the voltage at which the comparators 21 through 24 are inverted is set lower than the inverting voltage for the disconnection/high-voltage detecting circuit 10 illustrated in FIG. 1 by varying the reference voltages Vr12 through Vr42 or by varying the ratios of the voltage-sensing resistors Rs13 through Rs44.

The outputs of the comparators 21 through 24 are connected to the inputs of the OR circuit 25. The output from the OR circuit 25, i.e., the detection signal VLS, is input to the determination circuit 125. The control circuit 110 is identical to that of FIG. 1 with the exception that the input is changed from the high voltage detection signal VHout to a low-voltage detection signal VLout. The determination circuit 125 enclosed by a broken line is a circuit for determining whether low-voltage detection or disconnection detection should be made. The determination circuit 125 includes a logic circuit C126, a logic circuit D127, a delay circuit 128, and an OR circuit 129.

The logic circuit C126 receives the detection signal VLS from the disconnection/low-voltage detecting circuit 20 and a detection delay output VLSD from the delay circuit 128. The logic circuit C126 outputs the low-voltage detection signal VLout to an internal circuit (not illustrated). The logic circuit D127 receives the detection signal VLS from the disconnection/low-voltage detecting circuit 20, the disconnection confirmation signal LTEST from the control circuit 110, and the output VHSD from the delay circuit 128. The logic circuit D127 outputs a disconnection determination signal LCS as one of the inputs to the OR circuit 129. The delay circuit 128 receives the output VLS from the disconnection/low-voltage detecting circuit 20 and outputs the detection delay output VLSD to the logic circuits C and D. The OR circuit 129 receives the disconnection detection signal LCS from the logic circuit D127, an output from the VC1 disconnection detecting circuit 102, and an output from the inverter circuit 130. The OR circuit 129 outputs a disconnection detection signal LCout to an internal circuit (not illustrated).

The configuration of the determination circuit 125 is not particularly limited as long as it is capable of determining whether low-voltage detection or disconnection detection should be made.

Description of connections and configurations of the internal resistor changing circuit 101, the VC1 disconnection detecting circuit 102, and the VSS disconnection detecting circuit 103 is omitted as they are the same as illustrated in FIG. 1.

The delay circuit 128 is a circuit for setting a detection/recovery delay time for preventing erroneous detection due to noise and the like. Operation of the delay circuit 128 may be started when the output VLS from the OR circuit 25 is changed from L to H upon detection of a low-voltage. The delay circuit 128 may output a H pulse in the output VLSD when the output VLS from the OR circuit 25 is H until a set time elapses. Operation of the delay circuit 128 may also be started when the output VLS from the OR circuit 25 is changed from H to L upon recovery from the low-voltage detection status. The delay circuit 128 may output a H pulse in the output VLSD when the output VLS from the OR circuit 25 is L until a set time elapses.

While not illustrated, the output VLout from the logic circuit C 126 is input to the delay circuit 128 so that detection or recovery can be determined based on the status of the output VLout from the logic circuit C 126. The set time for low-voltage detection may differ from the set time for low-voltage recovery. The set time for high-voltage detection may differ from the set time for high-voltage recovery. The configuration of the delay circuit 128 is not particularly limited as long as it can perform the required operation.

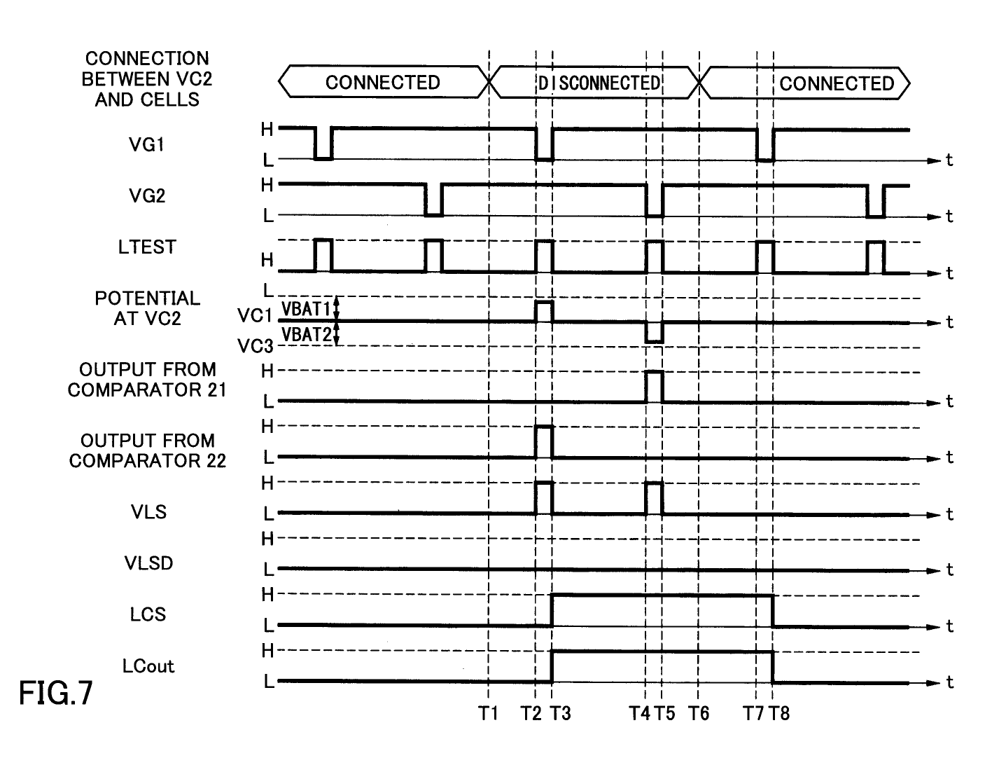

FIG. 7 is a timing chart of an operation of the protective semiconductor apparatus 2 according to the second embodiment for disconnection detection. The timing chart illustrates only those signals necessary for the description of the operation. With reference to FIG. 7, an operation of the circuit of FIG. 6 is described. It is assumed that the disconnection confirmation signal LTEST from the control circuit 110 and the control signals VG1 through VG4 are the same as the corresponding signals illustrated in FIG. 2, and that the disconnection confirmation time tpw is shorter than a delay time determined by the delay circuit 128.

For ease of description, it is assumed that the voltages VBAT1 through VBAT4 of the secondary cells BAT1 through BAT4, respectively, and the resistance values of the voltage-sensing resistors Rs13 through Rs44 in FIG. 2 have the following relationships:

VBAT1=VBAT2=VBAT3=VBAT4 (2.1)

Rs13+Rs14=Rs23+Rs24=Rs33+Rs34=Rs43+Rs44 (2.2)

The timing chart of FIG. 7 is described below along the time axis.

### <Time T1>

At time T1, disconnection occurs between the secondary cells and the cell connecting terminal VC2. At this time, a voltage V2F between the cell connecting terminals VC2 and VC3 is determined by voltage division by the voltage-sensing resistors Rs13 through Rs24 according to the following expression:

$$V 2 F = \frac{Rs 23 + Rs 24}{Rs 13 + Rs 14 + Rs 23 + Rs 24} \times ( VBAT 1 + VBAT 2 ) \qquad ( 2.3 )$$

According to the expressions (2.1), (2.2), and (2.3), the voltage V2F between the cell connecting terminals VC2 and VC3 is not changed from the voltage VBAT2 prior to disconnection. Thus, none of the outputs from the comparators 21 through 24 are changed.

### <Time T2>

At time T2, the disconnection confirmation signal LTEST from the control circuit 110 is switched from L to H, thus notifying the logic circuit D127 that disconnection detection confirmation is being made, while the control signal VG1 is switched from H to L in order to turn on the PMOS transistor M1. Thus, the internal resistor R11 is connected in parallel to the series circuit of the voltage-sensing resistors Rs13 and Rs14. Thus, a voltage V2G between the cell connecting terminals VC2 and VC3 is calculated by the following expression:

$$V 2 G = \frac{Rs 23 + Rs 24}{\frac{R 11 \times ( Rs 13 + Rs 14 )}{R 11 + Rs 13 + Rs 14} + Rs 23 + Rs 24} \times ( VBAT 1 + VBAT 2 ) \qquad ( 2.4 )$$

When the internal resistor R11 is sufficiently small compared to the sum of the voltage-sensing resistors Rs13 and Rs14 (which is the case in the present embodiment), the voltage between the cell connecting terminals VC2 and VC3 is substantially equal to a voltage V2H calculated by the following expression:

$$V 2 H = \frac{Rs 23 + Rs 24}{R 11 + Rs 23 + Rs 24} \times ( VBAT 1 + VBAT 2 ) \qquad ( 2.5 )$$

According to the expression (2.4) or (2.5), the potential at the cell connecting terminal VC2 is increased to approach the potential at the cell connecting terminal VC1, which is the connecting terminal for the positive electrode of the secondary cell BAT1. As a result, the voltage between the cell connecting terminals VC2 and VC3 is increased. Conversely, a voltage V1B between the cell connecting terminals VC1 and VC2 becomes lower according to an expression (2.6) indicated below. Thus, the comparator 21 detects a low-voltage and its output is inverted to the detection status H. As a result, the detection signal VLS from the disconnection/low-voltage detecting circuit 20 is inverted from L to H.

V1B=VBAT1+VBAT2−V2H (2.6)

### <Time T3>

At time T3, the disconnection confirmation signal LTEST from the control circuit 110 is switched from H to L, thus notifying the logic circuit D127 of the end of disconnection detection confirmation, while the control signal VG1 is switched from L to H in order to turn off the PMOS transistor M1. Thus, the parallel connection of the internal resistor R11 with the series circuit of the voltage-sensing resistors Rs13 and Rs14 is eliminated. As a result, the voltage between the cell connecting terminals VC2 and VC3 is returned to the voltage V2F according to the expression (2.3). As a result, the output from the comparator 11 is again inverted to the non-detection status L. Thus, the output from the disconnection/low-voltage detecting circuit 20, i.e., the detection signal VLS, is inverted from H to L.

Because the output VHSD from the delay circuit did not become H in the period in which the detection signal VLS from the disconnection/low-voltage detecting circuit 20 was H in accordance with the disconnection confirmation signal LTEST, the logic circuit D127 determines that there is disconnection, and inverts the disconnection determination signal LCS to the disconnection detection status H. In response to the disconnection determination signal LCS, the OR circuit 129 inverts its output, i.e., the disconnection detection signal LCout, to the disconnection detection status H.

### <Time T4>

At time T4, the disconnection confirmation signal LTEST from the control circuit 110 is switched from L to H, thus notifying the logic circuit D127 that disconnection detection confirmation is being made, while the control signal VG2 is switched from H to L in order to turn on the PMOS transistor M2. Thus, the internal resistor R21 is connected in parallel with the series circuit of the voltage-sensing resistors Rs23 and Rs24, so that the voltage between the cell connecting terminals VC2 and VC3 is a voltage V2J calculated by the following expression:

$$V 2 J = \frac{\frac{R 21 \times ( Rs 23 + Rs 24 )}{R 21 + Rs 23 + Rs 24}}{Rs 13 + Rs 14 + \frac{R 21 \times ( Rs 23 + Rs 24 )}{R 21 + Rs 23 + Rs 24}} \times ( VBAT 1 + VBAT 2 ) \qquad ( 2.7 )$$

When the internal resistor R21 is sufficiently small compared to the sum of the voltage-sensing resistors Rs23 and Rs24, the voltage between the cell connecting terminals VC2 and VC3 is substantially equal to a voltage V2K calculated by the following expression:

$$V 2 K = \frac{R 21}{Rs 13 + Rs 14 + R 21} \times ( VBAT 1 + VBAT 2 ) \qquad ( 2.8 )$$

According to the expression (2.7) or (2.8), the potential at the cell connecting terminal VC2 is lowered to approach the potential at the cell connecting terminal VC3, which is the connecting terminal for the negative electrode of the secondary cell BAT2. As a result, the voltage between the cell connecting terminals VC2 and VC3 is lowered. Thus, the comparator 22 detects a low-voltage and the output from the comparator 22 is inverted to the detection status H. Thus, the output from the disconnection/low-voltage detecting circuit 20, i.e., the detection signal VLS, is inverted from L to H.

### <Time T5>

At time T5, the disconnection confirmation signal LTEST from the control circuit 110 is switched from H to L, thus notifying the logic circuit D127 of the end of disconnection detection confirmation, while the control signal VG2 is switched from L to H in order to turn off the PMOS transistor M2. As a result, the parallel connection of the internal resistor R21 with the series circuit of the voltage-sensing resistors Rs23 and Rs24 is eliminated, whereby the voltage between the cell connecting terminals VC2 and VC3 is returned to the voltage V2F calculated by the expression (2.3). Thus, the output from the comparator 22 is again inverted to the non-detection status L, and the detection signal VLS from the disconnection/low-voltage detecting circuit 20 is inverted from H to L.

Because the output VHSD from the delay circuit did not become H in the period in which the output VLS from the disconnection/low-voltage detecting circuit 20 was H in accordance with the disconnection confirmation signal LTEST, the logic circuit D127 determines that there is disconnection, and thus maintains the disconnection determination signal LCS in the disconnection detection status H. In response to the disconnection determination signal LCS, the OR circuit 129 maintains its output, i.e., the disconnection detection signal LCout, in the disconnection detection status H.

### <Time T6>

At time T6, the disconnected portion is corrected in response to the disconnection detection.

### <Time T7>

At time T7, the disconnection confirmation signal LTEST from the control circuit 110 is switched from L to H, thus notifying the logic circuit D127 that disconnection detection confirmation is being made, while the control signal VG1 is switched from H to L in order to turn on the PMOS transistor M1. As a result, the internal resistor R11 is connected in parallel to the series circuit of the voltage-sensing resistors Rs13 and Rs14. However, as opposed to the case of the time between T2 and T3 or the time between T4 and T5, the power supply connecting terminal VC2 is connected to the secondary cells. Thus, the voltage between the cell connecting terminals VC2 and VC3 is not changed from the voltage VBAT2. Thus, the output VLS from the disconnection/low-voltage detecting circuit is not changed.

### <Time T8>

At time T8, the disconnection confirmation signal LTEST from the control circuit 110 is switched from H to L, thus notifying the logic circuit D127 of the end of disconnection detection confirmation, while the control signal VG2 is switched from L to H in order to turn off the PMOS transistor M2. Because the power supply connecting terminal VC3 is connected to the secondary cells as at time T7, the voltage between the cell connecting terminals VC2 and VC3 is not changed.

Because the output VHS from the disconnection/low-voltage detecting circuit 20 is not changed in accordance with the disconnection confirmation signal LTEST, the logic circuit D127 determines that the disconnection has been corrected and inverts the disconnection determination signal LCS to the recovered status L indicating recovery from disconnection. In response to the disconnection determination signal LCS, the OR circuit 129 inverts its output, i.e., the disconnection detection signal LCout, from the disconnection detection status to the recovered status L.

The operation is the same for the case of disconnection of the cell connecting terminal VC3 or VC4.

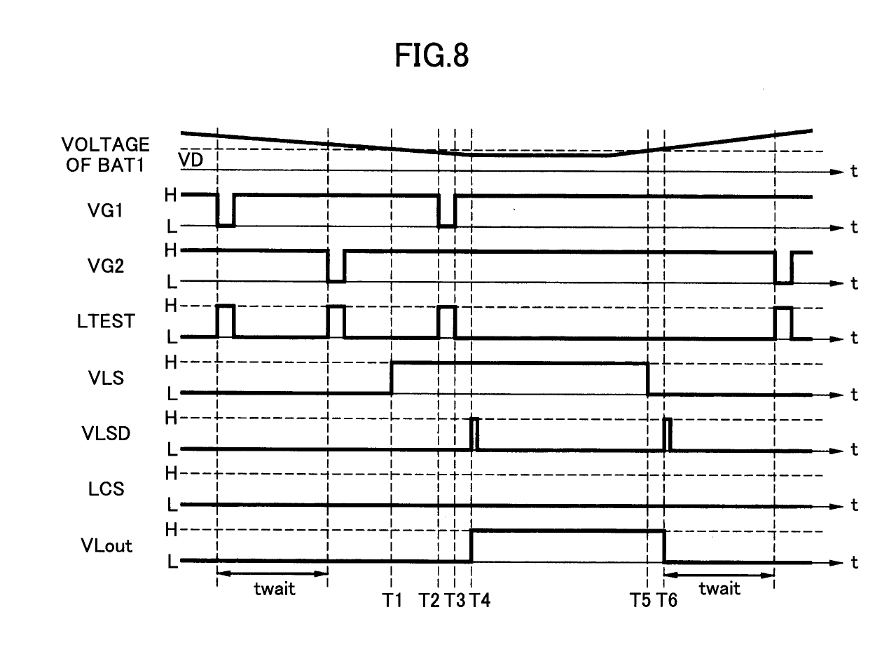

FIG. 8 is a timing chart of an operation of the protective semiconductor apparatus 2 according to the second embodiment upon low-voltage detection. The timing chart is described along the time axis.

### <Time T1>

After charging of the secondary cells is started from a time, the voltage VBAT1 of the secondary cell BAT1 drops below a low-voltage detection voltage VD at time T1. Because the voltage VBAT1 of the secondary cell BAT1 is lower than the low-voltage detection voltage VD, the output from the comparator 21 is inverted to H, and the detection signal VLS from the disconnection/low-voltage detecting circuit 20 is inverted to H.

### <Time T2>

At time T2, the disconnection confirmation signal LTEST from the control circuit 110 is switched from L to H, thus notifying the logic circuit D127 that disconnection detection confirmation is being made, while the control signal VG1 is switched from H to L in order to turn on the PMOS transistor M1. As a result, the internal resistor R11 is connected in parallel to the series circuit of the voltage-sensing resistors Rs13 and Rs14. However, because there is no disconnection, the cell connecting terminals VC1 through VC4 and the ground terminal VSS are not affected by the connection of the internal resistor R11. Because the voltage VBAT1 of the secondary cell BAT1 is lower than the low-voltage detection voltage VD, the detection signal VLS from the disconnection/low-voltage detecting circuit 20 is not changed and remains at H.

### <Time T3>

At time T3, the disconnection confirmation signal LTEST from the control circuit 110 is switched from H to L, thus notifying the logic circuit D127 of the end of disconnection detection confirmation, while the control signal VG2 is switched from L to H in order to turn off the PMOS transistor M2. However, because the voltage VBAT1 of the secondary cell BAT1 is lower than the low-voltage detection voltage VD, the detection signal VLS from the disconnection/low-voltage detecting circuit remains at H, as at time T2. As a result, the logic circuit D127 determines that there is no disconnection and maintains the disconnection determination signal LCS at L.

### <Time T4>

At time T4, the low-voltage detection delay time elapses, so that the delay circuit 128 outputs an H pulse in the output VLSD, and the logic circuit C126 inverts the low-voltage detection signal VLout from L to H. Because the protective semiconductor apparatus 2 is placed in a low-voltage detection status, the operation of the control circuit 110 is terminated by the low-voltage detection signal VLout.

### <Time T5>

The voltage VBAT1 of the secondary cell BAT1 increases due to charging, for example, and exceeds the low-voltage detection voltage VD at time T5, when the output from the comparator 21 is inverted to L. Thus, the output from the disconnection/low-voltage detecting circuit 20, i.e., the detection signal VLS, is inverted to L.

### <Time T6>

The delay time for recovery from low-voltage detection elapses at time T6, when the delay circuit 128 outputs a H pulse in the output VLSD and the logic circuit C126 inverts the low-voltage detection signal VLout from H to L. Thus, the protective semiconductor apparatus 2 is placed out of the low-voltage detection status, and therefore the operation of the control circuit 110 is resumed.

### Third Embodiment

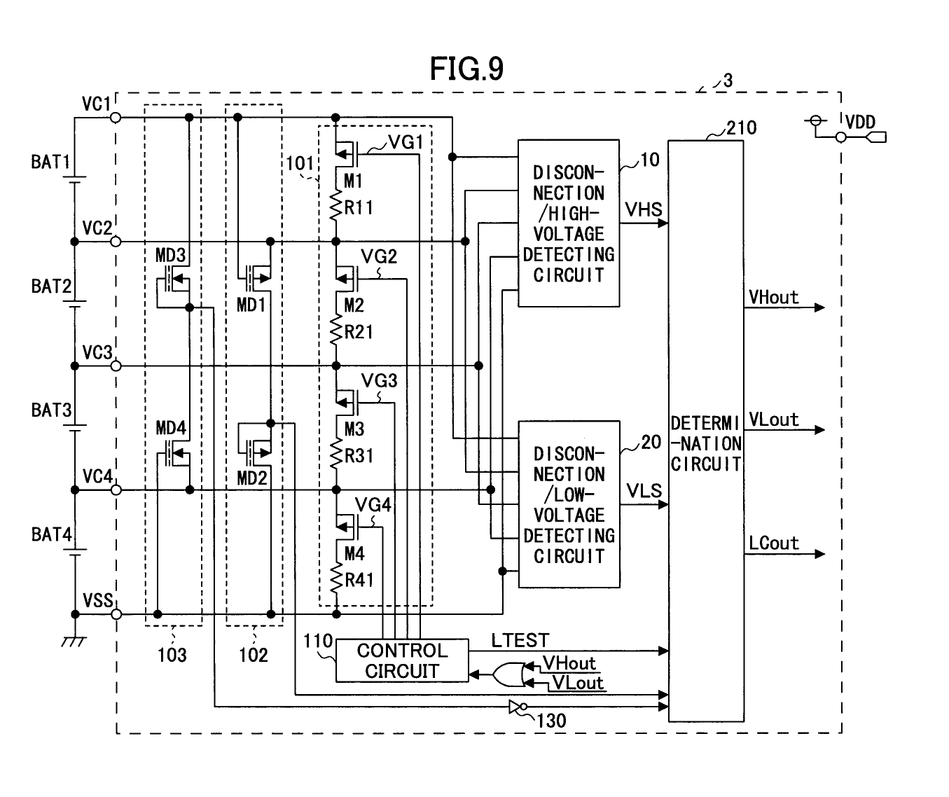

FIG. 9 is a connecting diagram of a protective semiconductor apparatus 3 according to the third embodiment. The protective semiconductor apparatus 3 is based on a combination of the first embodiment illustrated in FIG. 1 (including a disconnection/high-voltage detecting circuit) and the second embodiment illustrated in FIG. 6 (including a disconnection/low-voltage detecting circuit). While the illustrated example of FIG. 9 includes four secondary cells, the number of the secondary cells is not particularly limited.

The disconnection/high-voltage detecting circuit 10, the disconnection/low-voltage detecting circuit 20, the internal resistor changing circuit 101, the VC1 disconnection detecting circuit 102, and the VSS disconnection detecting circuit 103 illustrated in FIG. 9 may be identical to the corresponding circuits illustrated in FIGS. 1 and 6.

The third embodiment also differs from the first embodiment in that the control circuit 110 receives a signal of a logical OR of the high voltage detection signal VHout and the low-voltage detection signal VLout as an input, instead of the high voltage detection signal VHout in the example of FIG. 1.

The determination circuit 210 receives the output VHS from the disconnection/high-voltage detecting circuit 10, the output VLS from the low-voltage circuit 20, the disconnection confirmation signal LTEST from the control circuit 110, and output signals from the VC1 disconnection detecting circuit 102 and the VSS disconnection detecting circuit 103. The determination circuit 210 may output a high voltage detection signal VHout, a low-voltage detection signal VLout, or a disconnection detection signal LCout to a circuit (not illustrated).

Description of the internal configuration of the determination circuit 210 is omitted as the configuration is not particularly limited as long as it is capable of determining whether high-voltage detection, low-voltage detection, or disconnection detection should be made.

For detection of disconnection, the voltage-sensing resistors, the reference voltages, and the comparators of one of the disconnection/high-voltage detecting circuit 10 and the disconnection/low-voltage detecting circuit 20 may be used as described above. Alternatively, both the disconnection/high-voltage detecting circuit 10 and the disconnection/low-voltage detecting circuit 20 may be used and disconnection may be determined upon detection of disconnection by at least one of them.

### Fourth Embodiment

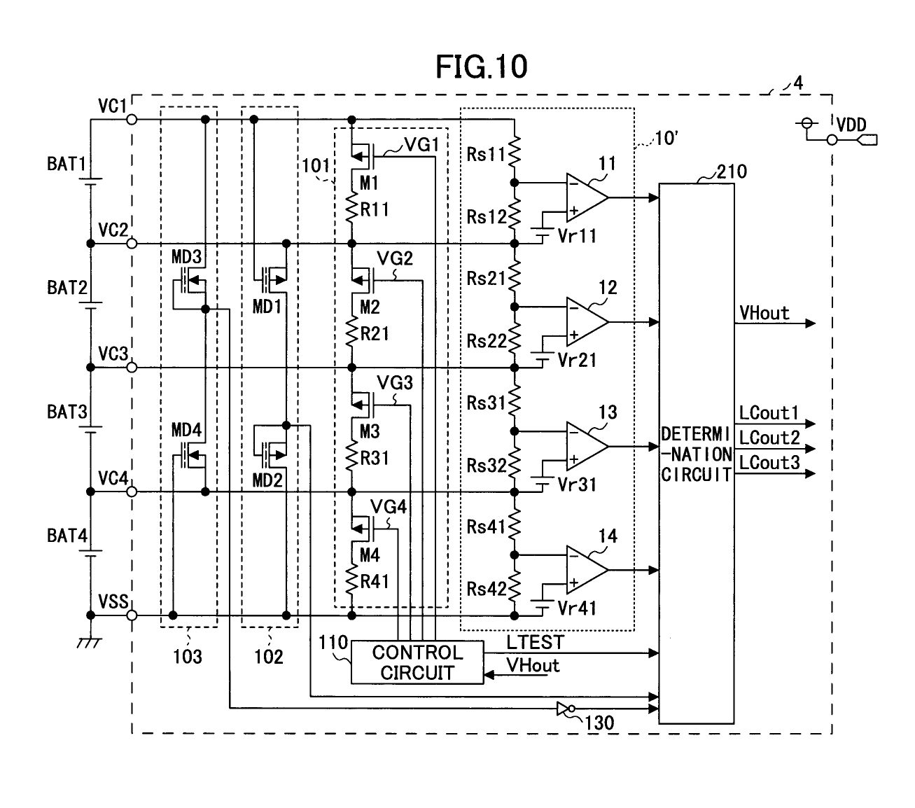

FIG. 10 is a connecting diagram of a protective semiconductor apparatus 4 according to the fourth embodiment of the present invention. The protective semiconductor apparatus 4 is based on a modification of the first embodiment of FIG. 1 such that it can be detected which connection is disconnected. The protective semiconductor apparatus 4 includes a disconnection/high-voltage detecting circuit 10′, an internal resistor changing circuit 101, a VC1 disconnection detecting circuit 102, a VSS disconnection detecting circuit 103, a control circuit 110, and a determination circuit 210.

While not illustrated, the protective semiconductor apparatus 4 may also include the disconnection/low-voltage detecting circuit 20 illustrated in FIG. 6 or an over-current detecting circuit. While the illustrated example of FIG. 10 includes four secondary cells, the number of the secondary cells is not particularly limited.

The disconnection/high-voltage detecting circuit 10′ differs from the disconnection/high-voltage detecting circuit 10 of FIG. 1 in that the NAND circuit 15 is omitted such that the outputs from the comparators 11 through 14 are directly supplied to the determination circuit 210. The internal configuration of the determination circuit 210 is not particularly limited as long as it is capable of determining whether high voltage detection or disconnection detection should be made, and, in the case of disconnection detection, which connection is disconnected (i.e., from which comparator the output L is coming from).

### Fifth Embodiment

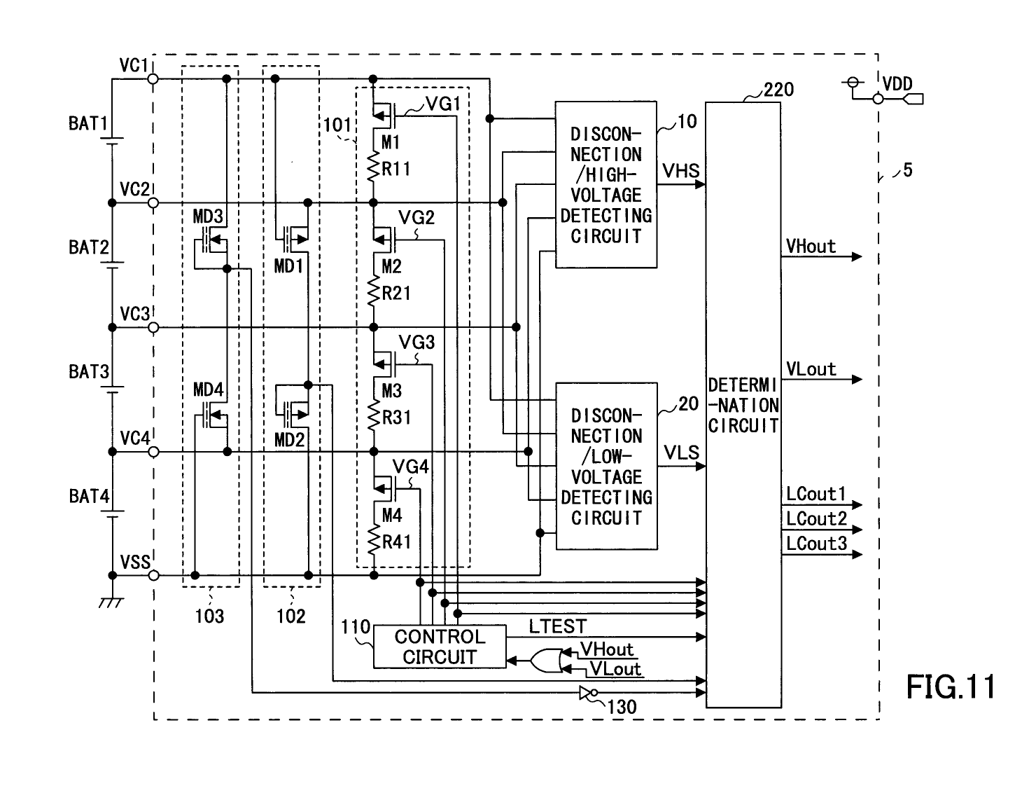

FIG. 11 is a connecting diagram of a protective semiconductor apparatus 5 according to the fifth embodiment. The protective semiconductor apparatus 5 differs from the protective semiconductor apparatus 3 of the third embodiment in that a function for determining which connection is disconnected is added. Specifically, the control signals VG1 through VG4 are supplied as input signals to the determination circuit 220, and the disconnection detection signal LCout includes three bits of LCout1 through LCout3 so that the determination circuit 210 can determine in which connection there is disconnection based on the input signals.

### Sixth Embodiment

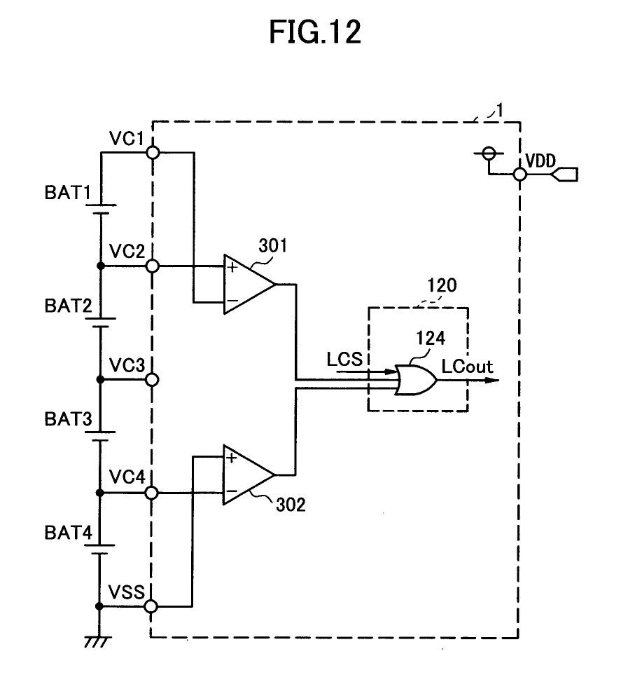

FIG. 12 is a connecting diagram of a protective semiconductor apparatus according to the sixth embodiment, in which comparators are used in a VC1 disconnection detecting circuit and a VSS disconnection circuit. The sixth embodiment differs from the first through fifth embodiments in that the VC1 disconnection detecting circuit and the VSS disconnection detecting circuit are realized with comparators instead of inverters.

As illustrated in FIG. 12, the VC1 disconnection detecting circuit for detecting disconnection between the cell connecting terminal VC1 and the protective semiconductor apparatus is provided by a comparator 301. The comparator 301 receives the potential at the cell connecting terminal VC1 as an inverting input and the potential at the cell connecting terminal VC2 for the negative electrode of the cell BAT1 (upper-most secondary cell) as a non-inverting input. The VSS disconnection detecting circuit for detecting disconnection between the ground terminal VSS and the protective semiconductor apparatus is provided by a comparator 302. The comparator 302 receives the potential (ground potential) at the ground terminal VSS as a non-inverting input and the potential at the cell-connecting terminal VC4 for the positive electrode of the BAT4 (lower-most secondary cell) as an inverting input.

In this structure, when the cell connecting terminal VC1 and the secondary cells are disconnected and the potential at the cell connecting terminal VC1 drops below the potential at the cell connecting terminal VC2, the comparator 301 determines that there is disconnection of the cell connecting terminal VC1 and outputs H. When the ground terminal VSS and the secondary cells are disconnected and the potential (ground potential) at the ground terminal VSS exceeds the potential at the cell connecting terminal VC4, the comparator 302 detects disconnection of the ground terminal VSS and outputs H.

### Seventh Embodiment

The protective semiconductor apparatus according to any of the foregoing embodiments may be contained in a battery pack. The size of the protective semiconductor apparatus or the battery pack is reduced by the sharing of some of their circuit components for different purposes. The protective semiconductor apparatus or the battery pack may be used in a variety of electronic devices, such as portable personal computers, audio devices, cameras, and video devices.

Although this invention has been described in detail with reference to certain embodiments, variations and modifications exist within the scope and spirit of the invention as described and defined in the following claims.

The present application is based on Japanese Priority Application No. 2010-159379 filed Jul. 14, 2010, the entire contents of which are hereby incorporated by reference.

1. A protective semiconductor apparatus for protecting an assembled battery including N secondary cells connected in series, the protective semiconductor apparatus comprising:
a disconnection detecting circuit including, for each of the N secondary cells, a voltage-sensing resistor configured to divide a voltage of the secondary cells;
a reference voltage; and
a first comparator configured to compare a voltage obtained by the voltage-sensing resistor with the reference voltage; and
a circuit configured to connect an internal resistor having a resistance value smaller than a resistance value of a corresponding one of the voltage-sensing resistors in parallel to the corresponding voltage-sensing resistors successively and selectively at predetermined time intervals,
wherein the disconnection detecting circuit is configured to detect disconnection between the N secondary cells and the protective semiconductor apparatus based on an output from the first comparator when the internal resistor is connected in parallel to the corresponding voltage-sensing resistor.

2. The protective semiconductor apparatus according to claim 1, further comprising:
a high-voltage detecting circuit including a second comparator configured to invert an output from the second comparator when the cell voltage of any one of the N secondary cells is increased to or above a predetermined first voltage; and/or
a low-voltage detecting circuit including a third comparator configured to invert an output from the third comparator when the cell voltage of any of the N secondary cells is decreased to or below a predetermined second voltage.

3. The protective semiconductor apparatus according to claim 2, wherein the voltage-sensing resistors and the reference voltages in the disconnection detecting circuit are shared with the high-voltage detecting circuit or the low-voltage detecting circuit, and
wherein the first comparator in the disconnection detecting circuit is shared as the second comparator in the high-voltage detecting circuit and/or as the third comparator in the low-voltage detecting circuit.

4. The protective semiconductor apparatus according to claim 3, wherein the first voltage in the high-voltage detecting circuit and the second voltage in the low-voltage detecting circuit are set by the voltage-sensing resistor and the reference voltage.

5. The protective semiconductor apparatus according to claim 1, wherein the circuit that connects the internal resistors to the corresponding voltage-sensing resistors successively and selectively is configured to connect a series circuit of the internal resistor and a switch in parallel to the corresponding voltage-sensing resistor and configured to turn on the switches successively and selectively.

6. The protective semiconductor apparatus according to claim 3, further comprising a determination circuit configured to determine disconnection between the N secondary cells and the protective semiconductor apparatus, an increase of the cell voltage of any of the N secondary cells to or above the first voltage, and/or a decrease of the cell voltage of any of the N secondary cells to or below the second voltage, based on the output from the first comparator, or the output from the first comparator and a timing signal for successively and selectively turning on the switches.

7. The protective semiconductor apparatus according to claim 6, wherein the determination circuit is configured to determine which power supply terminal of the N secondary cells is disconnected from the protective semiconductor apparatus.

8. The protective semiconductor apparatus according to claim 1, further comprising a circuit configured to detect disconnection between the protective semiconductor apparatus and a positive-electrode power-supply terminal of an upper-most one of the N secondary cells connected in series and/or a negative-electrode power-supply terminal of a lower-most one of the N secondary cells connected in series.

9. The protective semiconductor apparatus according to claim 8, wherein the circuit that detects disconnection between the positive-electrode power-supply terminal and the protective semiconductor apparatus includes an inverter configured to receive a potential at the positive-electrode power-supply connecting terminal.

10. The protective semiconductor apparatus according to claim 8, wherein the circuit configured to detect disconnection between the negative-electrode power-supply terminal and the protective semiconductor apparatus includes an inverter configured to receive a potential at the negative-electrode power-supply terminal.

11. The protective semiconductor apparatus according to claim 8, wherein the circuit configured to detect disconnection between the positive-electrode power-supply connecting terminal and the protective semiconductor apparatus includes a fourth comparator configured to receive a potential at the positive-electrode power-supply connecting terminal as an inverting input and a potential at a negative-electrode cell connecting terminal of the upper-most secondary cell as a non-inverting input.

12. The protective semiconductor apparatus according to claim 8, wherein the circuit configured to detect disconnection between the negative-electrode power-supply terminal and the protective semiconductor apparatus includes a fifth comparator configured to receive a potential at the negative-electrode power-supply terminal as a non-inverting input and a potential at a positive-electrode cell-connecting terminal of the lower-most secondary cell an inverting input.

13. The protective semiconductor apparatus according to claim 8, wherein the determination circuit is configured to detect disconnection between the positive-electrode power-supply connecting terminal and the protective semiconductor apparatus or disconnection between the negative-electrode power-supply terminal and the protective semiconductor apparatus.

14. The protective semiconductor apparatus according to claim 1, further comprising an oscillating circuit configured to set the time intervals at which the internal resistors are connected to the corresponding secondary cells successively and selectively.

15. The protective semiconductor apparatus according to claim 1, wherein the time intervals at which the internal resistors are connected to the corresponding secondary cells successively and selectively are controlled by adjusting the intervals of input of an external trigger signal.

16. The protective semiconductor apparatus according to claim 1, wherein the time intervals at which the internal resistors are connected to the corresponding secondary cells successively and selectively are set by an externally provided capacitor.

17. A battery pack comprising the protective semiconductor apparatus according to claim 1.

18. An electronic device comprising the protective semiconductor apparatus according to claim 1.
